(19) United States
(12) Patent Application Publication
(10) Pub. No.: US 2009/0152651 A1
(43) Pub. Date: Jun. 18, 2009

(54) GATE STACK STRUCTURE WITH OXYGEN GETTERING LAYER

(75) Inventors: Huiming Bu, Millwood, NY (US); Rick Carter, Hopewell Junction, NY (US); Michael P. Chudzik, Danbury, CT (US); Troy L. Graves, Wappingers Falls, NY (US); Michael A. Gribelyuk, Stamford, CT (US); Rashmi Jha, Wappingers Falls, NY (US); Vijay Narayanan, New York, NY (US); Dae-Gyu Park, Poughquaq, NY (US); Vamsi K. Paruchuri, New York, NY (US); Hongwen Yan, Somers, NY (US); Bruce B. Doris, Brewster, NY (US); Keith Kwong Hon Wong, Wappingers Falls, NY (US)

Correspondence Address: FREDERICK W. GIBB, III;Gibb Intellectual Property Law Firm, LLC, 2568-A RIVA ROAD, SUITE 304, ANNAPOLIS, MD, 21401, US

(73) Assignees: INTERNATIONAL BUSINESS MACHINES CORPORATION, ARMONK, NY (US); AMD, SUNNYVALE, CA (US)

(21) Appl. No.: 11/958,595

(22) Filed: Dec. 18, 2007

(51) Int. Cl. H01L 29/78

(52) U.S. Cl. 257/411; 257/E29.255

(57) ABSTRACT

A transistor has a channel region in a substrate and source and drain regions in the substrate on opposite sides of the channel region. A gate stack is formed on the substrate above the channel region. This gate stack comprises an interface layer contacting the channel region of the substrate, and a high-k dielectric layer (having a dielectric constant above 4.0) contacting (on) the interface layer. A Nitrogen rich first metal Nitride layer contacts (is on) the dielectric layer, and a metal rich second metal Nitride layer contacts (is on) the first metal Nitride layer. Finally, a Polysilicon cap contacts (is on) the second metal Nitride layer.

### BACKGROUND

### Field of the Invention

Embodiments herein generally relate to transistor structures, and more particularly to an improved metal gate structure having an Oxygen gettering layer.

### SUMMARY

As explained in U.S. Patent Publication 2007/0138563 (incorporated herein by reference) polysilicon used to be the standard gate material. One advantage of using polysilicon gates is that they can sustain high temperatures. However, there are some problems associated with using a polysilicon gates and, therefore, metal gates are becoming more popular.

Further, as explained in U.S. Patent Publications 2005/0280104 and 2007/0141797 (incorporated herein by reference) the gate dielectric for metal oxide semiconductor field of fact transistor (MOSFET) devices has in the past typically comprised silicon dioxide, which has a dielectric constant of about less than 4.0. However, as devices are scaled down in size, using silicon dioxide as a gate dielectric material becomes a problem because of gate leakage current, which can degrade device performance. Therefore, there is a trend in the industry towards the development of the use of high dielectric constant (k) materials for use as the gate dielectric material of MOSFET devices. The term “high k material” as used herein refers to a dielectric material having a dielectric constant of about 4.0 or greater.

The embodiments herein solve a problem that occurs for metal gates with high-k dielectrics that relates to re-growth of the interface layer below the gate dielectric. This re-growth inhibits Oxygen gettering, and therefore decreases device performance. The re-growth is more severe for narrow width devices, which are most relevant for high performance logic circuits.

In order to address this issue, embodiments herein provide a transistor having a channel region in the substrate and source and drain regions in the substrate on opposite sides of the channel region. A gate stack is formed on the substrate above the channel region. This gate stack comprises an interface layer contacting the channel region of the substrate, and a high-k dielectric layer (having a dielectric constant above 4.0) contacting (on) the interface layer. A Nitrogen rich first metal Nitride layer contacts (is on) the dielectric layer, and a metal rich second metal Nitride layer contacts (is on) the first metal Nitride layer. Finally, a Polysilicon cap contacts (is on) the second metal Nitride layer.

The excess metal within the second metal Nitride layer getters Oxygen, and the excess Nitrogen within the first metal Nitride layer improves charge trapping characteristics within the first metal Nitride layer.

In an alternative embodiment, the gate stack comprises a single metal Nitride layer contacting the dielectric layer. This single metal Nitride comprises a graded amount of metal and Nitrogen, such that the lower portion of the metal Nitride layer adjacent the high-k dielectric comprises excess Nitrogen and the upper portion of the metal Nitride layer adjacent the Polysilicon cap comprises excess metal. In this embodiment, the excess metal within the upper portion of the metal Nitride layer getters Oxygen, and the excess Nitrogen within the lower portion of the metal Nitride layer improves charge trapping characteristics within the metal Nitride layer.

These, and other, aspects and objects of the present invention will be better appreciated and understood when considered in conjunction with the following description and the accompanying drawings. It should be understood, however, that the following description, while indicating preferred embodiments of the present invention and numerous specific details thereof, is given by way of illustration and not of limitation. Many changes and modifications may be made within the scope of the present invention without departing from the spirit thereof, and the invention includes all such modifications.

### BRIEF DESCRIPTION OF THE DRAWINGS

The invention will be better understood from the following detailed description with reference to the drawings, in which:

FIG. 1 is a schematic cross-sectional diagram of an integrated circuit structure according to embodiments herein;

FIG. 2 is a schematic cross-sectional diagram of an integrated circuit structure according to embodiments herein; and

FIG. 3 is a schematic cross-sectional diagram of an integrated circuit structure according to embodiments herein.

### DETAILED DESCRIPTION OF EMBODIMENTS

The present invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the present invention. The examples used herein are intended merely to facilitate an understanding of ways in which the invention may be practiced and to further enable those of skill in the art to practice the invention. Accordingly, the examples should not be construed as limiting the scope of the invention.

As mentioned above there is a problem that occurs for metal gates with high-k dielectrics that relates to re-growth of the interface layer below the gate dielectric. Gettering layers have been used previously; however, gettering layers are traditionally placed directly on top of the high-k gate dielectric. The present inventors have found that gettering layers placed on top of (contacting) the high-k gate dielectric will scavenge Oxygen from the high-k and interfacial layer itself, resulting in a non-uniform interfacial layer which causes excessive charge trapping and edge leakage. This degrades total device performance.

Furthermore, the present inventors have discovered that Oxygen diffusion into the dielectric during downstream process steps, like resist removal, causes interfacial re-growth. For desirable device performance, the diffusion of Oxygen into the dielectric during downstream process steps should be controlled while maintaining the integrity of high-k and interfacial layer.

In view of this, the present embodiments have an “N-rich metal” contacting the gate dielectric and a “gettering layer” on top of the gate dielectric. Nitrogen (N) rich metals improve the charge trapping characteristics and edge leakage of the device, while the Oxygen gettering layer can getter Oxygen during the downstream process steps. Thus, the gate stack embodiments herein result in a uniform thickness of high-k and interfacial layer, with improved device characteristics.

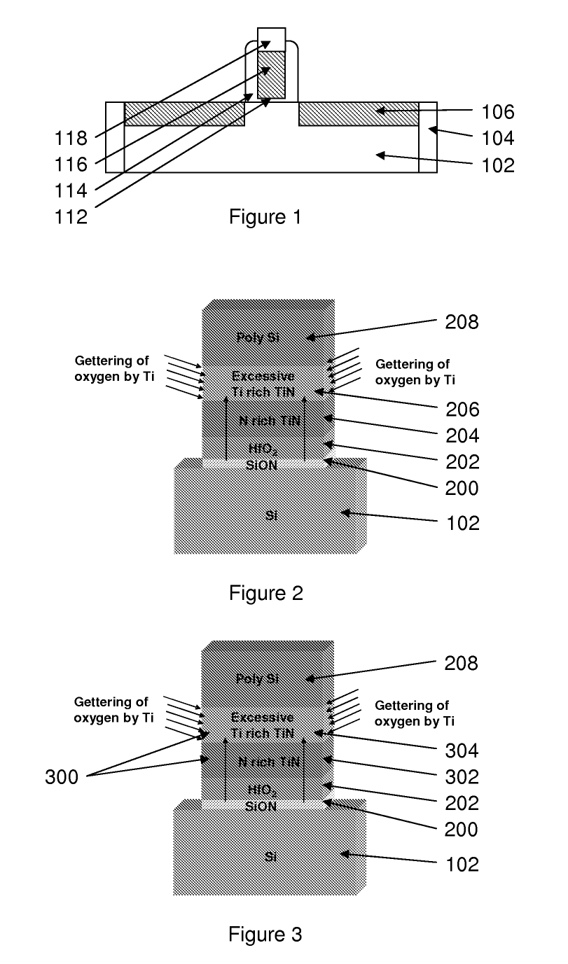

FIG. 1 illustrates a typical field effect transistor upon which embodiments herein operate. Such a field effect transistor includes a substrate 102 having a channel region; shallow trench isolation regions 104; source/drain regions 106; a gate dielectric 112; a gate conductor 114 above the gate oxide 112; a gate 118 at the top of the gate conductor 116; sidewall spacers 114 along the sides of the gate conductor 116; and an etch stop layer (nitride) 108. The various deposition, patterning, polishing, etching, etc. processes that are performed and the material selections that are made in the creation of such field effect transistors are well known as evidence by U.S. Pat. No. 6,995,065 (which is incorporated herein by reference) and the details of such processing are not discussed herein to focus the reader on the salient aspects of the invention. Further, while one type of specific device is illustrated in the drawings, those ordinarily skilled in the art would understand that the invention is not strictly limited to the specific device shown, but instead that the invention is generally applicable to all forms of transistor devices.

FIG. 2 illustrates just the gate stack of the transistor shown in FIG. 1 in greater detail. More specifically, as shown in FIG. 2, in one embodiment, The gate stack comprises an interface layer 200 contacting the channel region of the substrate 102, and a high-k dielectric layer 202 (having a dielectric constant above 4.0) contacting (on) the interface layer 200. A Nitrogen rich first metal Nitride layer 204 contacts (is on) the dielectric layer, and a metal rich second metal Nitride layer 206 contacts (is on) the first metal Nitride layer. Finally, a Polysilicon cap 208 contacts (is on) the second metal Nitride layer.

The excess metal within the second metal Nitride layer 206 getters Oxygen, and the excess Nitrogen within the first metal Nitride layer 204 improves charge trapping characteristics within the first metal Nitride layer.

Examples of the foregoing layers can include, but are not limited to the following materials. The high k gate dielectric 202 may be HfO₂, ZrO₂ AlO₂, etc. The first metal gate layer 204 (which defines the work function) may be TiN, TaN, W or any other appropriate metal. The second metal layer 206 (oxygen gettering layer) may be pure metal Ti, Hf, Ta, W and/or their nitrides etc.

In an alternative embodiment, shown in FIG. 3, the gate stack comprises a single metal Nitride layer 300 contacting the dielectric layer 202. This single metal Nitride comprises a graded amount of metal and Nitrogen, such that the lower portion of the metal Nitride layer 302 adjacent the high-k dielectric 202 comprises excess Nitrogen and the upper portion of the metal Nitride layer 304 adjacent the Polysilicon cap 208 comprises excess metal. In this embodiment, the excess metal within the upper portion of the metal Nitride layer 304 getters Oxygen, and the excess Nitrogen within the lower portion of the metal Nitride layer 302 improves charge trapping characteristics within the metal Nitride layer 300.

The details of the various foregoing processes including mask formation and patterning, epitaxial growth, etc. are well known to those ordinarily skilled in the art and the details of such processes are not described herein so as to focus the reader on the salient aspects of the invention. For example, U.S. Patent Publication 2007/0254464 (incorporated herein by reference) discusses many of the details of such processes.

Thus, as shown above, the embodiments herein use a Nitrogen lean metal nitride to act as an Oxygen gettering layer and to reduce interfacial re-growth (i.e. width effect) by gettering Oxygen from downstream processes like resist strip etc. Conventional structures only use pure Ti or Ta etc., as Oxygen gettering layer instead of N-lean nitride alloy of these metals. This results in a non-uniform interfacial layer and degrades the reliability of the devices due to excessive charge trapping based on PBTI measurements (where PBTI refers to Positive Bias Temperature Instability which is a method for measuring the charge trapping) and edge leakage.

Therefore, the inventive structure uses a “N-rich metal nitride” contacting the gate dielectric and a “gettering layer.” Nitrogen (N) rich metal nitrides improve the charge trapping characteristics and edge leakage of the device, while the Oxygen gettering layer can getter Oxygen during the downstream process steps. So the inventive gate stack results in a uniform thickness of high-k and interfacial layer with improved device characteristics. Furthermore, the Oxygen gettering layer in the proposed gate stack of the present disclosure can be N-lean TiN, which makes the implementation easier in a manufacturing environment.

Thus, the embodiments herein provide a gate stack configuration where a Nitrogen-rich metal Nitride gate electrode is capped with a metal-rich metal Nitride film. While the Nitrogen-rich metal Nitride serves the purpose of improving mobility and charge trapping, the metal-rich metal Nitride acts as an Oxygen getter which can significantly minimize the Oxygen diffusion to the gate dielectric, thus minimizing the re-growth of the interface layer. This structure results in overall better short channel affects with minimal degradation in the mobility and reliability of the device.

While the invention has been described in terms of preferred embodiments, those skilled in the art will recognize that the invention can be practiced with modification within the spirit and scope of the appended claims.

What is claimed is:

1. A structure comprising:
a substrate;
a channel region in said substrate;
source and drain regions in said substrate on opposite sides of said channel region; and
a gate stack on said substrate above said channel region,
wherein said gate stack comprises:
an interface layer contacting said channel region of said substrate;
a high-k dielectric layer having a dielectric constant above 4.0 contacting said interface layer;
a Nitrogen rich first metal Nitride layer contacting said dielectric layer;
a metal-rich second metal layer contacting said first metal Nitride layer (or any such oxygen-gettering metal); and
a Polysilicon cap contacting said second metal layer.

2. The structure according to claim 1, all limitations of which are hereby incorporated by reference, wherein excess metal within said second metal layer getters Oxygen.

3. The structure according to claim 1, all limitations of which are hereby incorporated by reference, wherein excess Nitrogen within said first metal Nitride layer improves charge trapping characteristics within said first metal Nitride layer.

4. A structure comprising:
a substrate;
a channel region in said substrate;
source and drain regions in said substrate on opposite sides of said channel region; and
a gate stack contacting said substrate above said channel region,
wherein said gate stack comprises:
an interface layer contacting said channel region of said substrate;
a high-k dielectric layer having a dielectric constant above 4.0 contacting said interface layer;
a metal Nitride layer contacting said dielectric layer; and
a Polysilicon cap contacting said metal Nitride layer,
wherein said metal Nitride comprises a graded amount of metal and Nitrogen such that a lower portion of said metal Nitride layer adjacent said high-k dielectric comprises excess Nitrogen and an upper portion of said metal Nitride layer adjacent said Polysilicon cap comprises excess metal.

5. The structure according to claim 4, all limitations of which are hereby incorporated by reference, wherein said excess metal within said upper portion of said metal Nitride layer getters Oxygen.

6. The structure according to claim 4, all limitations of which are hereby incorporated by reference, wherein said excess Nitrogen within said lower portion of said metal Nitride layer improves charge trapping characteristics within said metal Nitride layer.
